(19) United States
(12) Patent Application Publication
(10) Pub. No.: US 2026/0075943 A1
(43) Pub. Date: Mar. 12, 2026

(54) ARRAY SUBSTRATE, MANUFACTURING METHOD THEREOF, AND DISPLAY PANEL THEREOF

(71) Applicant: Guangzhou China Star Optoelectronics Semiconductor Display Technology Co., LTd., Guangzhou (CN)

(72) Inventor: Fangmei LIU, Guangzhou (CN)

(73) Assignee: Guangzhou China Star Optoelectronics Semiconductor Display Technology Co., LTd., Guangzhou (CN)

(21) Appl. No.: 18/964,424

(22) Filed: Nov. 30, 2024

(30) Foreign Application Priority Data
Sep. 9, 2024 (CN) 202411259168.4

(51) Int. Cl. H01L 21/02

(52) U.S. Cl. CPC H10D 86/441; H10D 86/0231; H10D 86/451

(57) ABSTRACT

The present application provides an array substrate, a manufacturing method thereof, and a display panel thereof. The array substrate includes an underlay substrate, an active layer, a gate insulation layer, a conductive layer, and a first electrode. The active layer includes a channel part, a first conductor part, and a second conductor part. The conductive layer includes a gate electrode and a drain electrode. An orthographic projection of the gate electrode on the active layer is located in the channel part. The drain electrode overlaps a part of the first conductor part. The first electrode is connected to the second conductor part. Along a direction from the first conductor part to the second conductor part, the first conductor part includes a first length, the second conductor part includes a second length, and the first length is greater than the second length.

### CROSS REFERENCE TO RELATED APPLICATIONS

The present application claims the priority to Chinese Patent Application No. 202411259168.4, filed on September 9, 2024. The entire disclosures of the above application are incorporated herein by reference.

### FIELD OF INVENTION

The present application relates to a field of display technologies, especially to an array substrate and a manufacturing method thereof, display panel.

### BACKGROUND OF INVENTION

In current display panels, a top gate indium gallium zinc oxide thin film transistor (Top gate IGZO TFT) is used to reduce the parasitic capacitor. However, a number of masks required to form a thin film transistor with a top gate structure is greater than a number of masks needed to form a thin film transistor with a bottom gate structure, resulting in increased costs and more processes.

To reduce the number of masks required in the fabrication process of the thin film transistor with a top gate structure, a conventional display panel forms the gate electrode, source electrode, and drain electrode layers using the same metal layer, thereby reducing the number of masks. However, the structure requires via holes to be opened on both sides of the gate insulation layer to electrically connect the source electrode and drain electrode with the corresponding conductor-activated layer, increasing the size of the thin film transistor and preventing further increases in the pixel density of the display panel.

### SUMMARY OF INVENTION

An embodiment of the present application provides an array substrate and a manufacturing method thereof, display panel to solve a technical issue of a low density of pixels in a conventional display panel.

The embodiment of the present application provides an array substrate, comprising:

an underlay substrate;

an active layer disposed on a side of the underlay substrate, wherein the active layer comprises a channel part and a first conductor part and a second conductor part disposed on two sides of the channel part respectively;

a gate insulation layer comprising a first insulation part and a second insulation part spaced from each other, wherein the first insulation part is disposed on a side of the active layer away from the underlay substrate, and the second insulation part is disposed on an end of the active layer;

a conductive layer disposed on a side of the gate insulation layer away from the underlay substrate, wherein the conductive layer comprises a gate electrode and a drain electrode separated from each other, the gate electrode is located on the first insulation part, an orthographic projection of the gate electrode on the active layer is located in the channel part; the drain electrode is located on the second insulation part, and the drain electrode overlaps a part of the first conductor part; and

a first electrode disposed on a side of the conductive layer away from the underlay substrate, wherein the first electrode is connected to the second conductor part;

wherein along a direction from the first conductor part to the second conductor part, the first conductor part comprises a first length, the second conductor part comprises a second length, and the first length is greater than the second length.

In the array substrate of the present application, a ratio of the first length to the second length ranges from 1.2 to 2.

In the array substrate of the present application, a first via hole is defined between the first insulation part and the second insulation part, the drain electrode contacts a sidewall of the second insulation part and extends along the sidewall to a surface of a side of the first conductor part away from the underlay substrate.

In the array substrate of the present application, the drain electrode comprises an overlap surface contacting the first conductor part, a length of the overlap surface along a direction from the first conductor part to the channel part ranges from 2 microns to 8 microns.

In the array substrate of the present application, the array substrate further comprises:

a first passivation layer disposed on a side of the conductive layer away from the underlay substrate;

a planarization layer disposed on a side of the first passivation layer away from the underlay substrate;

a common electrode disposed on a side of the planarization layer away from the underlay substrate; and

a second passivation layer disposed on a side of the common electrode away from the underlay substrate;

wherein a second via hole is defined in the array substrate and penetrates the second passivation layer, the planarization layer, and the first passivation layer, the first electrode is disposed on a side of the second passivation layer away from the underlay substrate, and the first electrode is connected to the second conductor part through the second via hole.

In the array substrate of the present application, a tilt angle of the second via hole is less than 70°.

In the array substrate of the present application, the array substrate further comprises:

a buffer layer disposed between the underlay substrate and the active layer; and

at least one transmission line configured to transmit a voltage signal, wherein the transmission line and the active layer are disposed on a surface of a side of the buffer layer away from the underlay substrate.

In the array substrate of the present application, a material of the transmission line is the same as a material of the first conductor part and/or a material of the second conductor part.

The present application also provides an array substrate manufacturing method, comprising:

providing an underlay substrate;

forming an active layer on the underlay substrate;

forming a gate insulation layer on the active layer and defining a first via hole in the gate insulation layer;

implementing a first conductivizing process to the active layer uncovered by the gate insulation layer;

forming a conductive material layer on the gate insulation layer and patterning the conductive material layer such that the conductive material layer forms a conductive layer comprising a gate electrode and a drain electrode, wherein the gate electrode and the drain electrode are separately disposed from each other;

by a self-alignment process, etching the gate insulation layer uncovered by the gate electrode and the drain electrode such that the gate insulation layer forms a first insulation part and a second insulation part spaced from each other, wherein the first insulation part is disposed on a side of the active layer away from the underlay substrate, the second insulation part is disposed at an end of the active layer, the gate electrode is located on the first insulation part, the drain electrode is located on the second insulation part, and the drain electrode overlaps the active layer corresponding to the first via hole;

implementing a second conductivizing process to the active layer uncovered by the gate electrode and the drain electrode such that the active layer corresponding to the gate electrode forms a channel part, the active layer connected to the channel part and near the drain electrode forms a first conductor part, and the active layer connected to the channel part and located away from the drain electrode forms a second conductor part; and

forming a first electrode, connected to the second conductor part, on a side of the conductive layer away from the underlay substrate;

wherein along a direction from the first conductor part to the second conductor part, the first conductor part comprises a first length, the second conductor part comprises a second length, and the first length is greater than the second length.

The present application also provides a display panel, comprising the above array substrate.

### DESCRIPTION OF DRAWINGS

Specific embodiments of the present invention are described in details with accompanying drawings as follows to make technical solutions and advantages of the present invention clear.

FIG. 1 is a first structural view of an array substrate provided by the present application.

FIG. 2 is a second structural view of the array substrate provided by the present application.

FIG. 3 is a structural top view of an active layer in the array substrate provided by the present application.

FIG. 4 is a structural view of a display panel provided by the present application.

FIG. 5 is a step flowchart of an array substrate manufacturing method provided by the present application.

FIGS. 6A to 6H are structural views of steps of the array substrate manufacturing method provided by the present application.

### DETAILED DESCRIPTION OF PREFERRED EMBODIMENTS

The technical solution in the embodiment of the present application will be clearly and completely described below with reference to the accompanying drawings in the embodiments of the present application. Apparently, the described embodiments are merely some embodiments of the present application instead of all embodiments. According to the embodiments in the present application, all other embodiments obtained by those skilled in the art without making any creative effort shall fall within the protection scope of the present application. In addition, it should be understood that the specific embodiments described here are only used to illustrate and explain the present application, and are not used to limit the present application.

In the description of the present application, it is to be understood that the terms "length," "width," "thickness," "upper," "lower," "front," "back," "left," "right," "top," "bottom," "inner," "outer," and other directional or positional terms are based on the orientation or positional relationships shown in the figures, provided solely for the convenience of describing the present application and simplifying the description, and are not intended to indicate or imply that the referenced device or element must have a specific orientation or be constructed and operated in a specific orientation. Therefore, they should not be construed as limitations on the present application.

Moreover, the terms "first" and "second" are used merely for descriptive purposes and should not be construed to indicate or imply relative importance or to implicitly specify the quantity of the technical features indicated. Thus, features denoted by "first" and "second" may expressly or implicitly include one or a plurality of features. In the description of the present application, "a plurality of" means two or more, while "at least one" can mean one, two, or more, unless otherwise specifically defined.

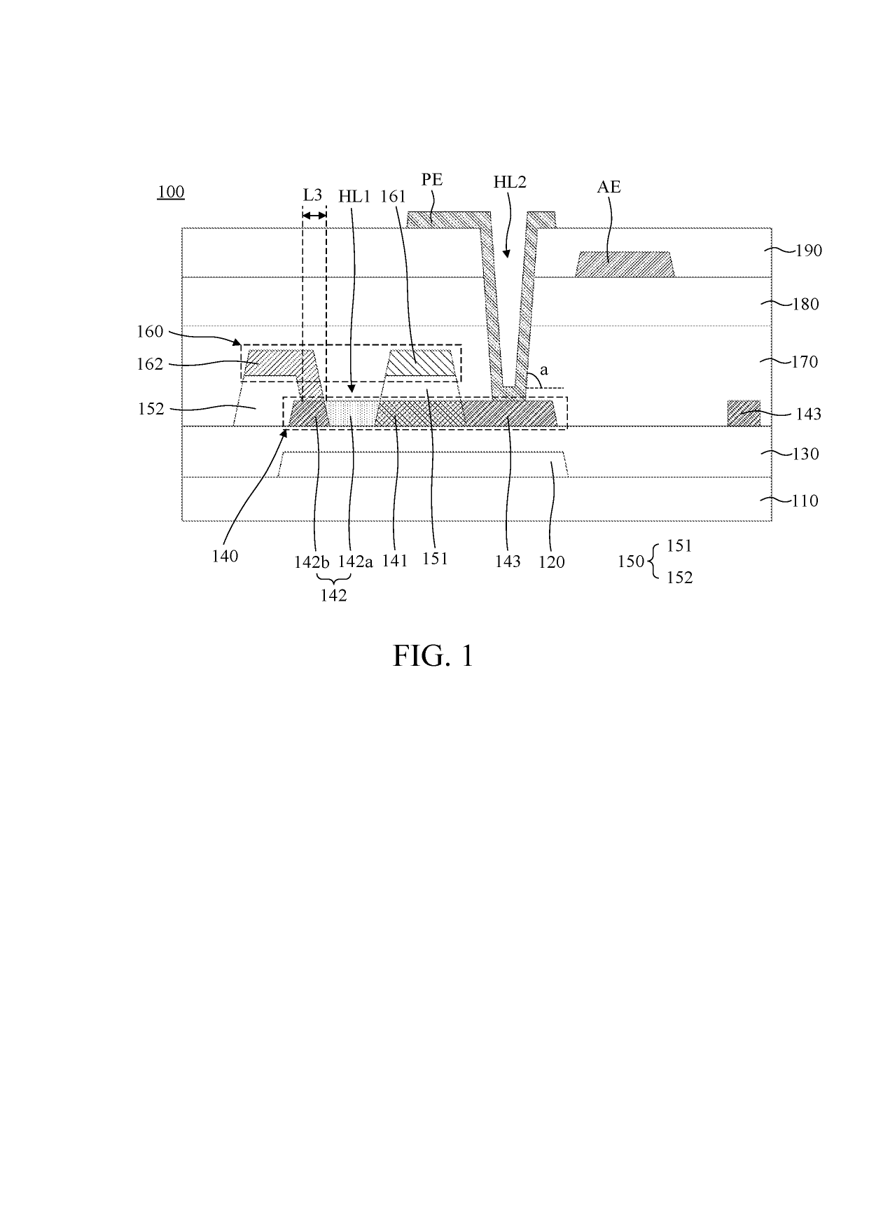

With reference to FIGS. 1 to 4, the embodiment of the present application provides an array substrate 100 comprising an underlay substrate 110, an active layer 140, a gate insulation layer 150, a conductive layer 160, and a first electrode PE. The active layer 140 is disposed on a side of the underlay substrate 110. The gate insulation layer 150 is disposed on a side of the active layer 140 away from the underlay substrate 110. The conductive layer 160 is disposed on a side of the gate insulation layer 150 away from the underlay substrate 110. The first electrode PE is disposed on a side of the conductive layer 160 away from the underlay substrate 110.

In the present embodiment, the active layer 140 comprises a channel part 141 and a first conductor part 142 comprises a second conductor part 143 disposed respectively on two sides of the channel part 141. The gate insulation layer 150 comprises a first insulation part 151 and a second insulation part 152 spaced from each other. the first insulation part 151 is disposed on a side of the active layer 140 away from the underlay substrate 110. The second insulation part 152 is disposed at an end of the active layer 140. The conductive layer 160 comprises a gate electrode 161 and a drain electrode 162 disposed separately from each other. The gate electrode 161 is located on the first insulation part 15. An orthographic projection of the gate electrode 161 on the active layer 140 is located in the channel part 141. The drain electrode 162 is located on the second insulation part 152, and the drain electrode 162 overlaps a part of the first conductor part 142. The first electrode PE is connected to the second conductor part 143.

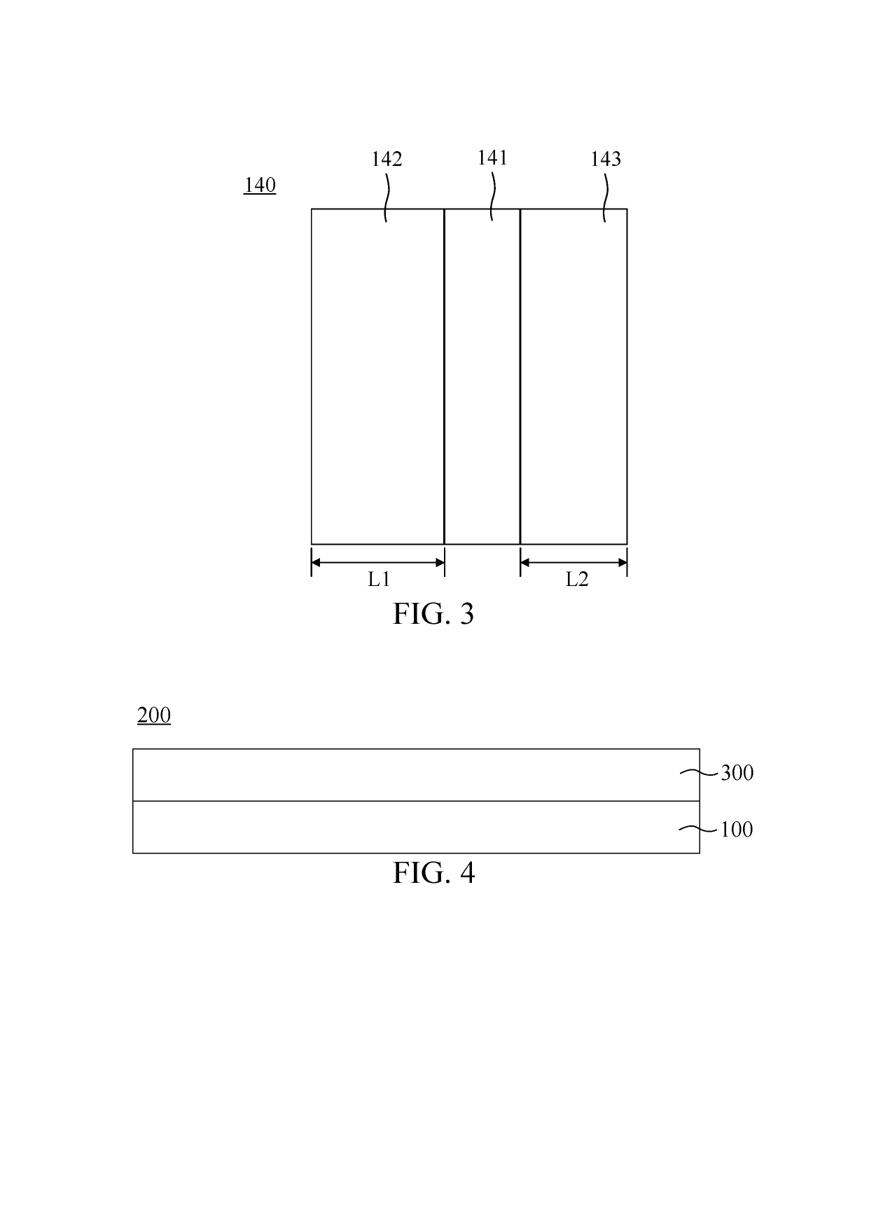

In the present embodiment, with reference to FIG. 3, along a direction from the first conductor part 142 to the second conductor part 143, the first conductor part 142 comprises a first length L1, the second conductor part 143 comprises a second length L2, and the first length L1 is greater than the second length L2.

In the embodiment, a ratio of the first length L1 to the second length L2 ranges from 1.2 to 2.

With reference to FIGS. 1 to 3, because the drain electrode 162 is connected to the first conductor part 142, and the first electrode PE is directly connected to the second conductor part 143, the second conductor part 143 can be reused as the source electrode, thereby omitting the source electrode. There is no need to set a source electrode contact hole configured to be connected to the drain electrode 162 in the gate insulation layer 150 in a region in which the second conductor part 143 is located. Also, the second length L2 of the second conductor part 143 is less than the first length L1 of the first conductor part 142, thereby reducing the length of the active layer 140. Namely, a size of a transistor in the array substrate 100 is reduced such that more transistors can be set in the product, thereby increasing a density of the pixels of the product.

The technical solution of the present application is described in combination with specific embodiments as follows.

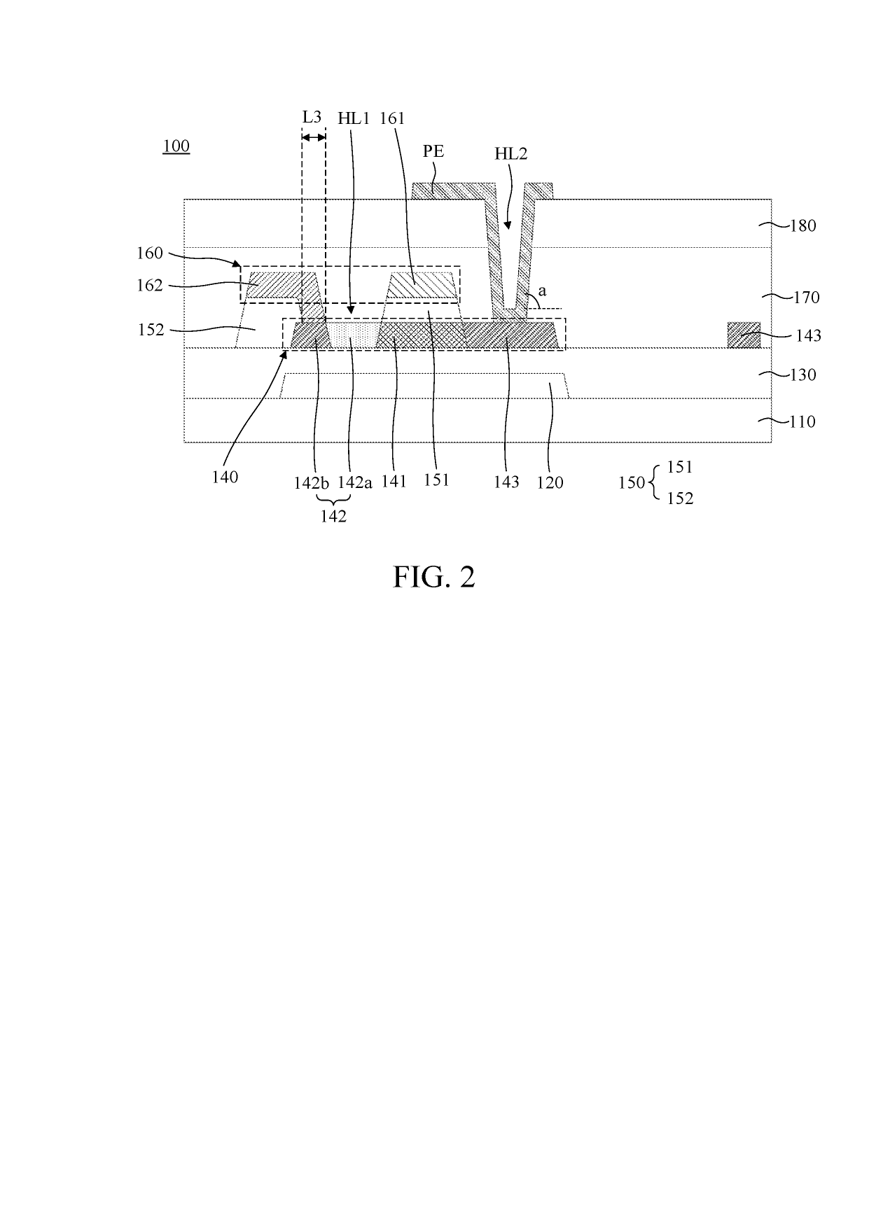

With reference to FIGS. 1 and 2, a material of the underlay substrate 110 can be a rigid underlay substrate, for example, the rigid material such as glass, or quartz. The material of the underlay substrate 110 can be a flexible underlay substrate, for example, the flexible material such as polyimide.

With reference to FIGS. 1 and 2, the array substrate 100 comprises a light shielding layer 120 disposed on a side of an underlay substrate 110. An orthographic projection of the active layer 140 on the light shielding layer 120 is located in the light shielding layer 120, thereby preventing a lowered device effect of the transistors due to light entering the channel part 141.

With reference to FIGS. 1 and 2, the light shielding layer 120 can be light shielding metal or other material with light shielding capability, for example, molybdenum, aluminum, copper, titanium, alloy of the above materials or a lamination layer of the above material.

In the present embodiment, a thickness of the light shielding layer 120 ranges from 1000 Å to 8000 Å.

With reference to FIGS. 1 and 2, the array substrate 100 further comprises a buffer layer 130 disposed on a side of the light shielding layer 120 away from the underlay substrate 110. The buffer layer 130 covers the light shielding layer 120, and is disposed in a form of an entire layer on the array substrate 100. A material of the buffer layer 130 can comprise a compound composed of nitrogen element, silicon element, and oxygen element, for example, the material of the buffer layer 130 can comprise a single layer of silicon oxide, or silicon oxide film layer, or a lamination layer structure of silicon oxide, silicon nitride, and aluminum oxide.

In the present embodiment, a thickness of the buffer layer 130 ranges from 6000 Å to 10000 Å.

With reference to FIG. 1 and FIG. 2, the array substrate 100 further comprises an active layer 140 disposed on a side of the buffer layer 130 away from the underlay substrate 110. The active layer 140 comprises a channel part 141 and a first conductor part 142 and a second conductor part 143 disposed respectively on two sides of the channel part 141.

In the present embodiment, the active layer 140 can utilize a physical vapor deposition process and be processed by a yellow light process and an etching process to form patterns. A material of the active layer 140 can be metal oxide, for example, IGZO, IGTO, Ln-IZO, ITZO, ITGZO, HIZO, IZO(InZnO), ZnO:F, In2O3:Sn, In2O3:Mo, Cd2SnO4, ZnO:Al, TiO2:Nb, Cd-Sn-O, or other metal oxide. The present application utilizes IGZO as an example for explanation in the following embodiment.

In the present embodiment, a thickness of the active layer 140 ranges from 400 Å to 1000 Å.

With reference to FIGS. 1 and 2, the array substrate 100 further comprises a gate insulation layer 150 disposed on a side of the active layer 140 away from the underlay substrate 110. The gate insulation layer 150 comprises a first insulation part 151 and a second insulation part 152 spaced from each other. A first via hole HL1 is defined between the first insulation part 151 and the second insulation part 152, and the first via hole HL1 exposes a part of the first conductor part 142.

In the present embodiment, a material of the gate insulation layer 150 can comprise a compound composed of nitrogen element, silicon element, and oxygen element. For example, the material of the gate insulation layer 150 can comprise a single layer of silicon oxide, or silicon oxide film layer, or a lamination layer structure of silicon oxide, silicon nitride, aluminum oxide.

In the present embodiment, a thickness of the gate insulation layer 150 ranges from 1000 Å to 3000 Å.

With reference to FIG. 1 and FIG. 2, the array substrate 100 further comprises a conductive layer 160 disposed on the gate insulation layer 150. A material of the conductive layer 160 can comprise metal such as Cr, W, Ti, Ta, Mo, Al, or Cu or a single layer or multilayer metal structure constituted by the above at least two metal. For example, the material of conductive layer 160 can be Mo, Mo/Al, Mo/Cu, MoTi/Cu, MoTi/Cu/MoTi, Ti/Al/Ti, Ti/Cu/Ti, Mo/Cu/IZO, IZO/Cu/IZO, or Mo/Cu/ITO.

In the present embodiment, a thickness of the conductive layer 160 ranges from 2000 Å to 8000 Å.

In the present embodiment, a yellow light process and an etching process can be used to pattern the conductive layer 160 such that the conductive layer 160 forms a pattern comprising the gate electrode 161 and the drain electrode 162. Second, the pattern of the conductive layer 160 is used to implement an self-alignment process to the gate insulation layer 150 to complete the patterning process to the gate insulation layer 150.

In the present embodiment, the gate electrode 161 is located on the first insulation part 151. The drain electrode 162 is located on the second insulation part 152. The gate electrode 161 corresponds to the channel part 141. Namely, the orthographic projection of the gate electrode 161 on the active layer 140 overlaps the channel part 141. The drain electrode 162 contacts a sidewall of the second insulation part 152 and extends along the sidewall to a surface of a side of the first conductor part 142 away from the underlay substrate 110 such that the drain electrode 162 is electrically connected to the first conductor part 142.

With reference to FIGS. 1 and 2, the array substrate 100 further comprises a first passivation layer 170 disposed on a side of the conductive layer 160 away from the underlay substrate 110. The first passivation layer 170 is disposed in a form of an entire layer. A thickness of the first passivation layer 170 ranges from 1000 Å to 5000 Å.

With reference to FIG. 1 and FIG. 2, the array substrate 100 further comprises a planarization layer 180 disposed on a side of the first passivation layer 170 away from the underlay substrate 11. The planarization layer 180 is disposed in a form of an entire layer. A material of the planarization layer 180 comprises a flexible material such as polytetrafluoroethylene (PTFE), and a thickness of the planarization layer 180 ranges from 10000 Å to 30000 Å.

With reference to FIG. 1, the array substrate 100 further comprises a common electrode AE disposed on a side of the planarization layer 180 away from the underlay substrate 110. A material of the common electrode AE can comprise ITO, IZO, ITO/Ag/ITO, IZO/Ag/IZO, Mo/Cu, MoTi/Cu/MoTi, etc.

With reference to FIG. 1, the array substrate 100 further comprises a second passivation layer 190 disposed on a side of the common electrode AE away from the underlay substrate 110, the second passivation layer 190 is disposed in a form of an entire layer. A thickness of the second passivation layer 190 ranges from 1000 Å to 5000 Å.

In the present embodiment, materials of the first passivation layer 170 and the second passivation layer 190 can be the same. The materials of the first passivation layer 170 and the second passivation layer 190 can comprise a compound composed of nitrogen element, silicon element, and oxygen element, for example, a single layer of silicon oxide, a silicon oxide film layer, or a laminated layer structure such as silicon oxide, silicon nitride, aluminum oxide, etc.

With reference to FIG. 1, the array substrate 100 further comprises a first electrode PE disposed on a side of the second passivation layer 190 away from the underlay substrate 110. A material of the first electrode PE can comprise ITO, IZO, ITO/Ag/ITO, IZO/Ag/IZO, Mo/Cu, MoTi/Cu/MoTi, etc.

In the present embodiment, a second via hole HL2 is defined in the array substrate 100 and penetrates the second passivation layer 190, the planarization layer 180, ans a part of the first passivation layer 170. The first electrode PE is disposed on a side of the second passivation layer 190 away from the underlay substrate 110, and the first electrode PE is connected to the second conductor part 143 through the second via hole HL2.

In the structures of FIGS. 1 and 2, because a thickness of the planarization layer 180 is greater, a depth of the second via hole HL2 is greater. To prevent a sidewall of the first electrode PE on the second via hole HL2 from, being broken, a tilt angle of the second via hole HL2 of the present application cannot be over large. For example, a tilt angle a of the second via hole HL2 of the present application can be less than 70°.

With reference to FIG. 2, the first electrode PE can be directly disposed on a side of the planarization layer 180 away from the underlay substrate 110. The first electrode PE can be connected to the second conductor part 143 through the second via hole HL2.

It should be explained that both the structures in FIGS. 1 and 2 can be adapted for liquid crystal display panel, the first electrode PE can be a pixel electrode. The structure of FIG. 2 can also be adapted for an organic light emitting diode display panel or a Mini light emitting diode (Mini-LED) or a Micro-LED. When the structure in FIG. 2 is adapted for the organic light emitting diode display panel, the first electrode PE can be an anode.

It should be explained that because the drain electrode 162 extends to the active layer 140 corresponding to the first via hole HL1, in a later conductivizing process, because of shielding of the drain electrode 162, a conductivizing process cannot be implemented to the active layer 140 contacting the drain electrode 162, the present application, after defining the first via hole HL1 in the gate insulation layer 150 needs to implement a first conductivizing process to the active layer 140 contacting the first via hole HL1. Also, after the patterning process to the conductive layer 160 is completed, a second conductivizing process needs to be implemented to the active layer 140 not shielded by the drain electrode 162, the gate electrode 161, and the gate insulation layer.

In the present embodiment, both the first conductivizing process and the second conductivizing process of the present application can be plasma processes to remove the oxygen element in the active layer 140.

It should be explained that because two conductivizing processes are implemented to the region in the first conductor part 142 not shielded by the drain electrode 162, and only one conductivizing process is implemented on the second conductor part 143, a concentration of the oxygen element of the first conductor part 142 of the present application not shielded by the drain electrode 162 can be less than a concentration of the oxygen element in the second conductor part 143. Namely, a resistivity of the first conductor part 142 is less than a resistivity of the second conductor part 143. Also, in the structures of FIGS. 1 and 2, the first conductor part 142 comprises a first part 142a and a second part 142b that are adjacent to each other. The first part 142a corresponds to the first via hole HL1. Because two conductivizing processes are implemented to the first part 142a, a concentration of the oxygen element of the first part 142a of the present application is less than a concentration of the oxygen element of the second part 142b. Namely, a resistivity of the first part 142a is less than a resistivity of the second part 142b.

In the present embodiment, to assure electrical connection of the drain electrode 162 with the first conductor part 142, a contact area between the drain electrode 162 and the first conductor part 142 can not be over small. For example, the drain electrode 162 comprises an overlap surface contacting the first conductor part 142, and a length L3 of the overlap surface along a direction from the first conductor part 142 to the channel part 141 ranges from 2 microns to 8 microns.

Because the gate electrode 161 and the drain electrode 162 are formed by the same metal layer, one metal layer and one insulation layer insulatively disposed between two metal layers are substantially omitted. This process can reduce a number of the masks. However, due to reduction the number of of the metal layers, a wiring space of metal wirings in the product is limited.

In the present embodiment, with reference to FIGS. 1 and 2, the array substrate 100 further comprises at least one transmission line 143 configured to transmit a voltage signal. Both the transmission line 143 and the active layer 140 are disposed on a surface of the buffer layer 130, and a material of the transmission line 143 is the same as a material of the first conductor part 142 and/or the second conductor part 143. Namely, the present application, whiling manufacturing the active layer 140, can also utilize the material of the active layer 140 to manufacture the transmission line 143 configured to transmit the voltage signal in the display panel, for example, a high electric potential line, a low electric potential line, a clock signal line, an initial signal line, a data signal line, etc.

With reference to FIG. 4, the present application also provides a display panel 200 comprising the above array substrate 100 and a light emitting member 300 disposed on a side of the array substrate 100. When the display panel 200 is a liquid crystal display panel, the light emitting member 300 can be a backlight module, and a side of the display panel 200 away from the light emitting member 300 is a light exiting side. When the display panel 200 is an organic light emitting diode display panel, the light emitting member 300 can be an organic light emitting diode. When the display panel 200 is a direct-lit display panel, the light emitting member 300 can be a Mini-LED or Micro-LED.

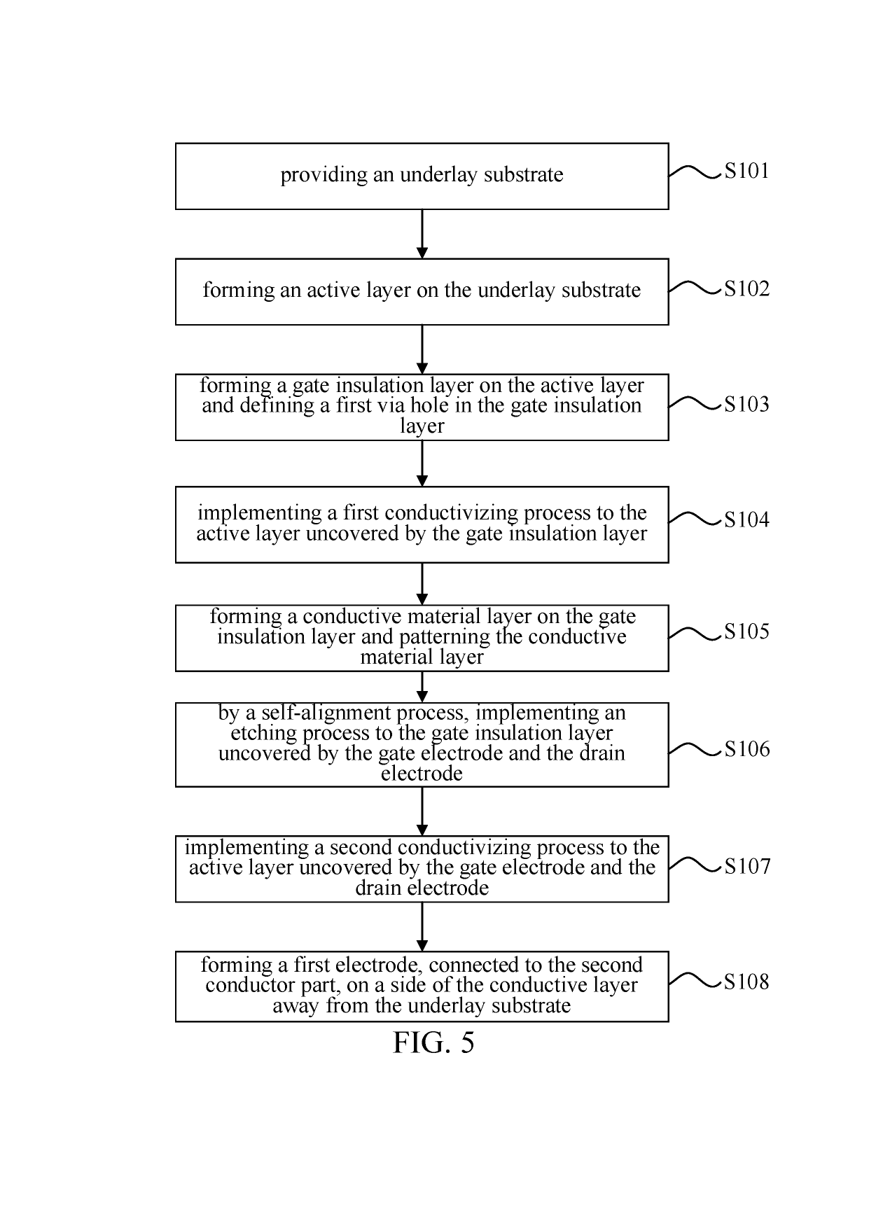

With reference to FIG. 5, the present application also provides a method for manufacturing an array substrate 100, comprising steps as follows:

A step S101 comprises providing an underlay substrate 110.

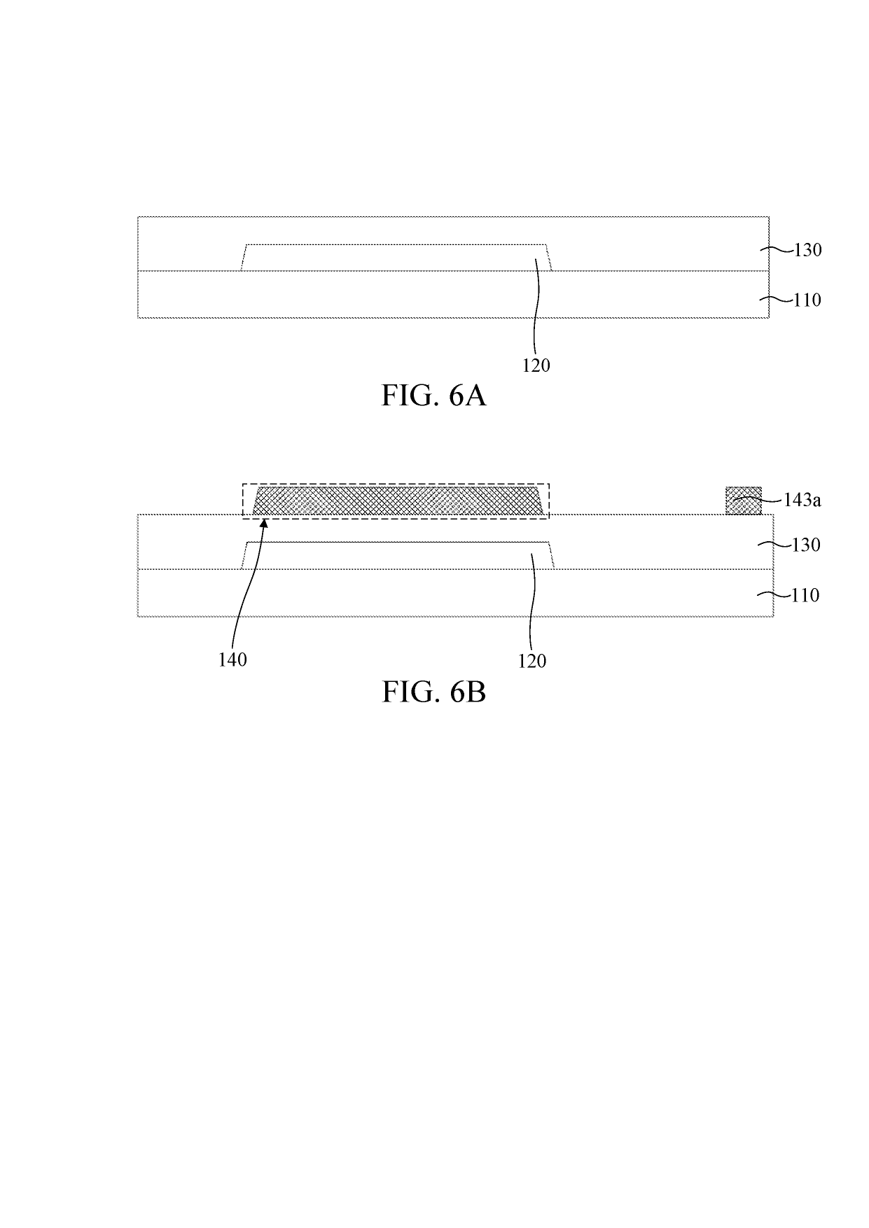

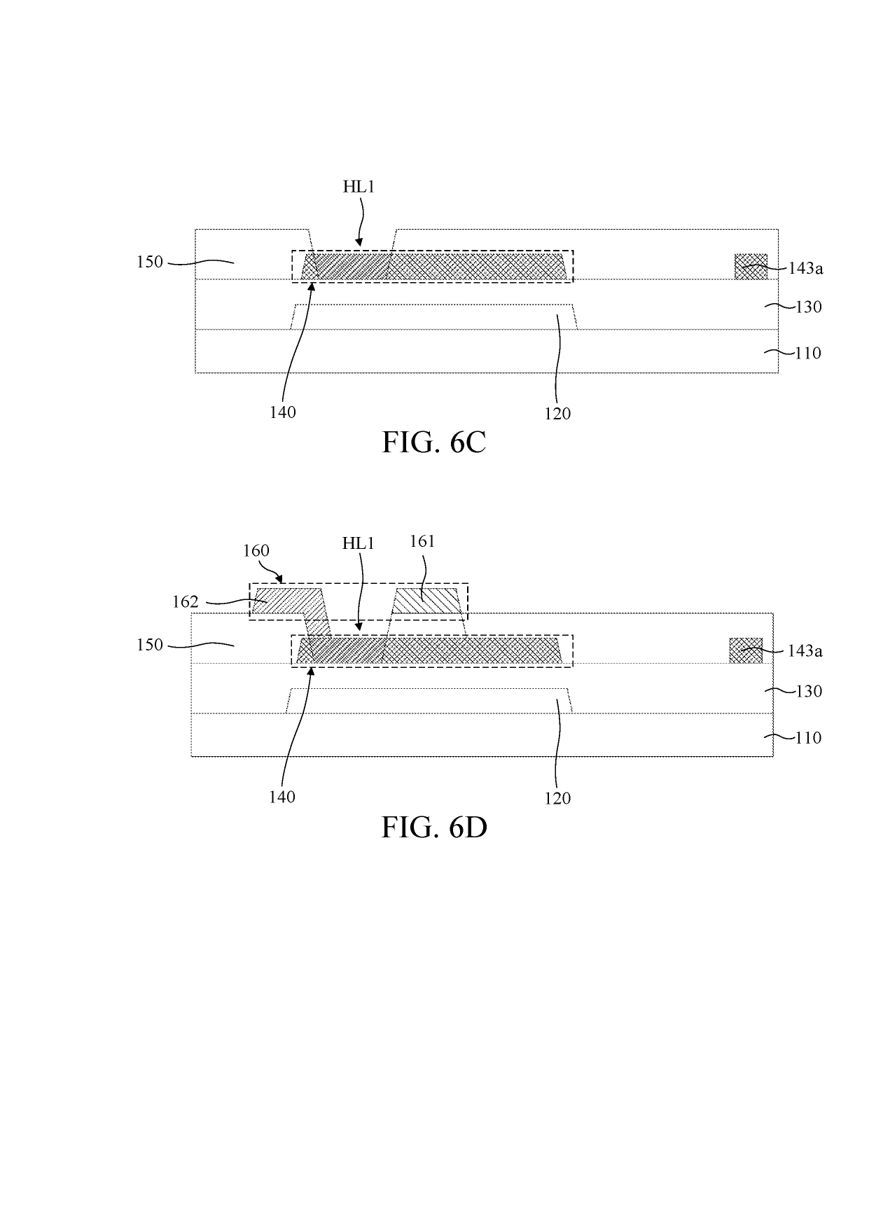

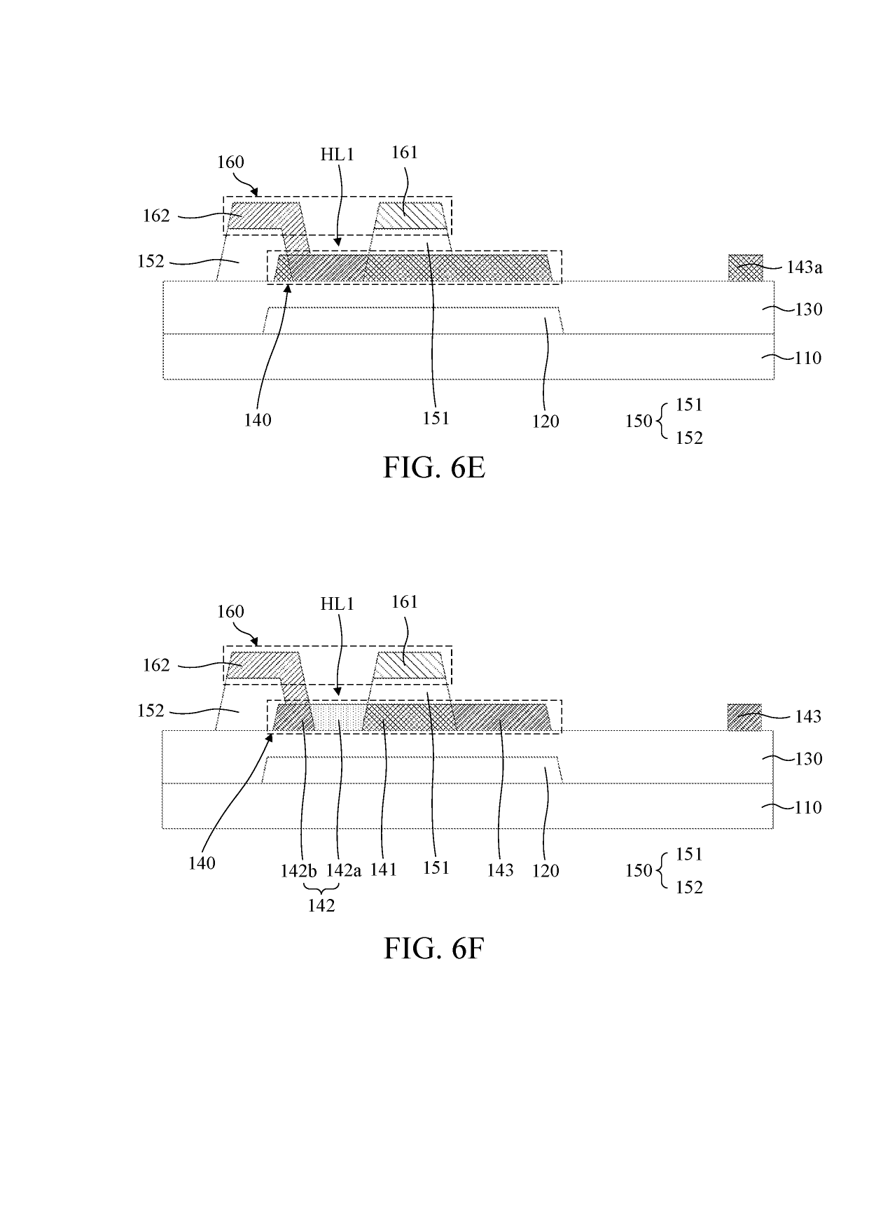

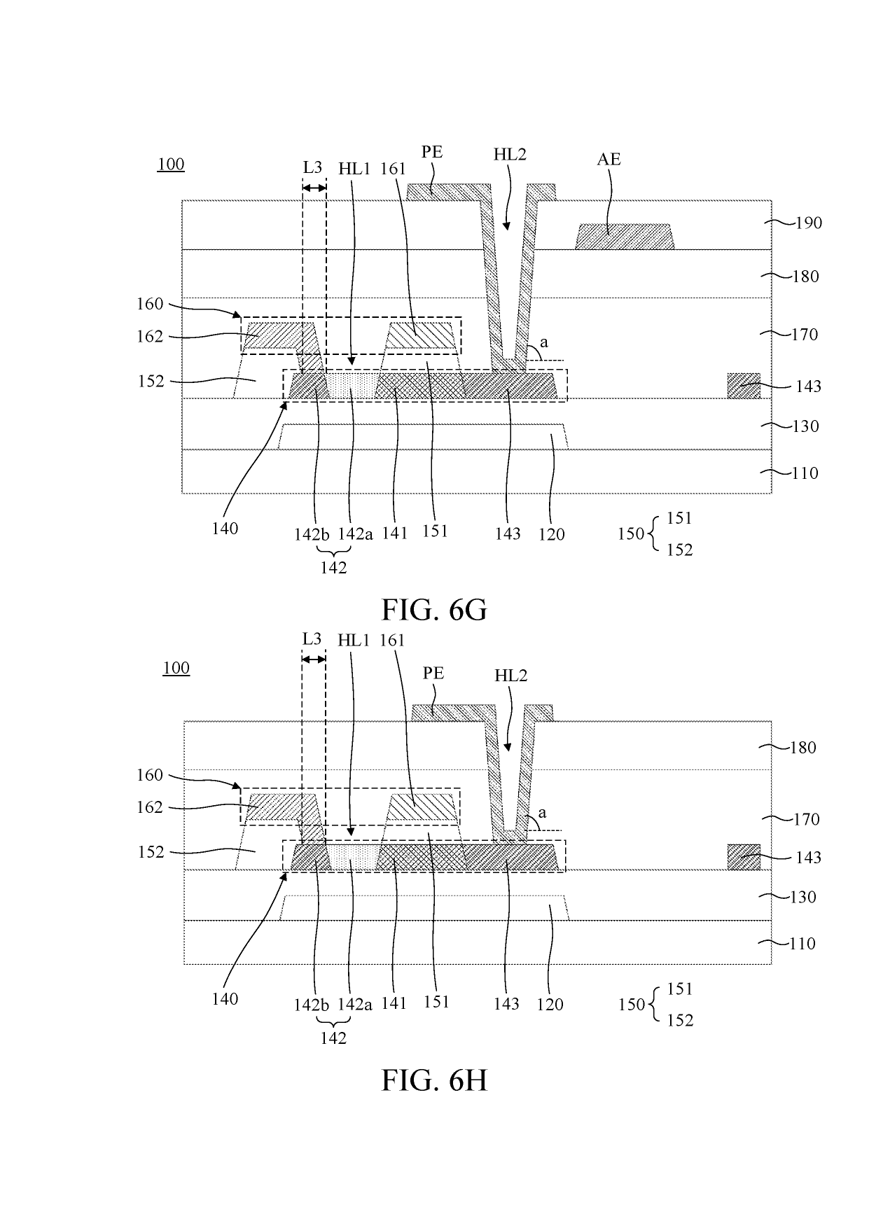

With reference to FIG. 6A, a material of the underlay substrate 110 can be a rigid underlay substrate, for example, the rigid material such as glass, or quartz. The material of the underlay substrate 110 can be a flexible underlay substrate, for example, the flexible material such as polyimide.

Before a step S102, the method further comprises: forming a light shielding layer 120 and a buffer layer 130 on the underlay substrate 110.

With reference to FIG. 6A, the light shielding layer 120 can be light shielding metal or other material with light shielding capability. The light shielding layer 120 is patterned to form the structure as shown in FIG. 6A. The buffer layer 130 covers the light shielding layer 120 and is disposed in a form of an entire layer on the array substrate 100.

The step S102 comprises forming an active layer 140 on the underlay substrate 110.

With reference to FIG. 6B, the active layer 140 can utilize a physical vapor deposition process and be processed by a yellow light process and an etching process to form patterns. A material of the active layer 140 can be metal oxide, for example, IGZO, IGTO, Ln-IZO, ITZO, ITGZO, HIZO, IZO(InZnO), ZnO:F, In2O3:Sn, In2O3:Mo, Cd2SnO4, ZnO:Al, TiO2:Nb, Cd-Sn-O, or other metal oxide. The present application utilizes IGZO as an example for explanation in the following embodiment.

With reference to FIG. 6B, when the active layer 140 is formed on the buffer layer 130, at least one active line 143a is also formed on the buffer layer 130. A material of the active line 143a is the same as a material of the active layer 140, and the active line 143a and the active layer 140 are formed by the same mask process.

A step S103 comprises forming a gate insulation layer 150 on the active layer 140 and defining a first via hole HL1 in the gate insulation layer 150.

With reference to FIG. 6C, the gate insulation layer 150 is disposed in a form of an entire layer to completely cover the active layer 140. Also, for a later conductivizing process, the first via hole HL1 of the current step exposes a part of the active layer 140.

A step S104 comprises implementing a first conductivizing process to the active layer 140 uncovered by the gate insulation layer 150.

With reference to FIG. 6C, the first conductivizing process of the present application can be a plasma process to remove the oxygen element in the active layer 140 uncovered by the gate insulation layer 150 to conductivize the active layer 140 uncovered by the gate insulation layer 150.

A step S105 comprises forming a conductive material layer on the gate insulation layer 150 and patterning the conductive material layer such that the conductive material layer forms the conductive layer 160 comprising a gate electrode 161 and a drain electrode 162, wherein the gate electrode 161 and the drain electrode 162 are disposed separately from each other.

With reference to FIG. 6D, the step S105 comprises: forming a conductive material layer on the gate insulation layer 150; and by a yellow light process and an etching process, patterning the conductive layer 160 such that the conductive layer 160 forms a pattern comprising a gate electrode 161 and a drain electrode 162.

In the present embodiment, a material of the conductive layer 160 can be Mo, Mo/Al, Mo/Cu, MoTi/Cu, MoTi/Cu/MoTi, Ti/Al/Ti, Ti/Cu/Ti, Mo/Cu/IZO, IZO/Cu/IZO, or Mo/Cu/ITO.

A step S106 comprises by a self-alignment process, implementing an etching process to the gate insulation layer 150 uncovered by the gate electrode 161 and the drain electrode 162 such that the gate insulation layer 150 forms a first insulation part 151 and a second insulation part 152 spaced from each other. The first insulation part 151 is disposed on a side of the active layer 140 away from the underlay substrate 110. The second insulation part 152 is disposed at an end of the active layer 140. The gate electrode 161 is located on the first insulation part 151. The drain electrode 162 is located on the second insulation part 152, and the drain electrode 162 overlaps the active layer 140 corresponding to the first via hole HL1.

With reference to FIG. 6E, the patterns of the gate electrode 161 and source electrode 162 in the conductive layer 160 are used as a mask and a self-alignment process is implemented to the gate insulation layer 150 to remove the gate insulation layer 150 uncovered by the gate electrode 161 and the drain electrode 162 such that the gate insulation layer 150 forms a first insulation part 151 and a second insulation part 152 spaced from each other.

A step S107 comprises implementing a second conductivizing process to the active layer 140 uncovered by the gate electrode 161 and the drain electrode 162 such that the active layer 140 corresponding to the gate electrode 161 forms a channel part 141, the active layer 140 connected to the channel part 141 and located near the drain electrode 162 forms a first conductor part 142, and the active layer 140 connected to the channel part 141 and located away from the drain electrode 162 forms a second conductor part 143.

With reference to FIG. 6F, the second conductivizing process of the present application can be a plasma process to remove the oxygen element in the active layer 140 not shielded by the drain electrode 162, the gate electrode 161, and the gate insulation layer 150 such that a part of the active layer 140 near the drain electrode 162 forms a first conductor part 142, and a part of the active layer 140 away from the drain electrode 162 forms a second conductor part 143.

In the present embodiment, because two conductivizing processes are implemented to the region of the first conductor part 142 not shielded by the drain electrode 162 and only one conductivizing process is implemented to the second conductor part 143, a concentration of the oxygen element in the first conductor part 142 not shielded by the drain electrode 162 of the present application can be less than a concentration of the oxygen element in the second conductor part 143. Namely, a resistivity of the first conductor part 142 is less than a resistivity of the second conductor part 143. Also, in the structure of FIG. 6F, the first conductor part 142 comprises the first part 142a and the second part 142b adjacent to each other. The first part 142a corresponds to the first via hole HL1. Because the first conductivizing process and the second conductivizing process are implemented to the first part 142a, and the first conductivizing process and the second conductivizing process are only implemented to the second part 142b, the present application a concentration of the oxygen element of the first part 142a is less than a concentration of the oxygen element of the second part 142b. Namely, a resistivity of the first part 142a is less than a resistivity of the second part 142b.

In the step, along the direction from the first conductor part 142 to the second conductor part 143, the first conductor part 142 comprises a first length L1, the second conductor part 143 comprises a second length L2, and the first length L1 is greater than the second length L2.

Also, because the drain electrode 162 is connected to the first conductor part 142, and the first electrode PE is directly connected to the second conductor part 143, the second conductor part 143 can be reused as the source electrode, thereby omitting the source electrode. There is no need to set a source electrode contact hole configured to be connected to the drain electrode 162 in the gate insulation layer 150 in a region in which the second conductor part 143 is located. Also, the second length L2 of the second conductor part 143 is less than the first length L1 of the first conductor part 142, thereby reducing the length of the active layer 140. Namely, a size of a transistor in the array substrate 100 is reduced such that more transistors can be set in the product, thereby increasing a density of the pixels of the product..

In the step, because the active line 143a is not shielded by the gate insulation layer 150, the active line 143a, by a second conductivizing process, forms a transmission line 143 configured to transmit a voltage signal. For example, the transmission line 143 can be a high electric potential line, a low electric potential line, a clock signal line, an initial signal line, a data signal line, etc.

A step S108 comprises forming a first electrode PE, connected to the second conductor part 143, on a side of the conductive layer 160 away from the underlay substrate 110.

With reference to FIG. 6G, before the step S108, the method further comprises: forming a first passivation layer 170 on a side of the conductive layer 160 away from the underlay substrate 110; forming a planarization layer 180 on a side of the first passivation layer 170 away from the underlay substrate 110; forming a common electrode AE on a side of the planarization layer 180 away from the underlay substrate 110; and forming a second passivation layer 190 on a side of the common electrode AE away from the underlay substrate 110.

It should be explained that in each process of the first passivation layer 170, the planarization layer 180, and the second passivation layer 190, a via hole is required to expose a part of the second conductor part 143. The via holes in the first passivation layer 170, the planarization layer 180, and the second passivation layer 190 are formed continuously to form the second via hole HL2.

With reference to FIG. 6G, the first electrode PE is electrically connected to the second conductor part 143 through the second via hole HL2.

In the present embodiment, materials of the buffer layer 130, the gate insulation layer 150, the first passivation layer 170, and the second passivation layer 190 can comprise a compound composed of nitrogen element, silicon element, and oxygen element, for example, a single layer of silicon oxide, a silicon oxide film layer, or a laminated layer structure such as silicon oxide, silicon nitride, aluminum oxide, etc.

In the present embodiment, a material of the planarization layer 180 comprises a flexible material such as polytetrafluoroethylene (PTFE).

In the present embodiment, materials of the first electrode PE and the common electrode AE can comprise ITO, IZO, ITO/Ag/ITO, IZO/Ag/IZO, or Mo/Cu, MoTi/Cu/MoTi.

With reference to FIG. 6H, before the step S108, the method further comprises: forming a first passivation layer 170 on a side of the conductive layer 160 away from the underlay substrate 110; and forming a planarization layer 180 on a side of the first passivation layer 170 away from the underlay substrate 110.

With reference to FIG. 6H, the first electrode PE can be directly disposed on a side of the planarization layer 180 away from the underlay substrate 110. The first electrode PE can be connected to the second conductor part 143 through the second via hole HL2.

In the structures of FIGS. 6G and 6H, because the thickness of the planarization layer 180 is greater, a depth of the second via hole HL2 is greater. To prevent a sidewall of the first electrode PE on the second via hole HL2 from being broken, the tilt angle of the second via hole HL2 of the present application cannot be over large. For example, the tilt angle a of the second via hole HL2 of the present application can be less than 70°.

It should be explained that both the structures in FIGS. 6G and 6H can be adapted for the liquid crystal display panel. The first electrode PE can be a pixel electrode. The structure in FIG. 6H can also be adapted for the organic light emitting diode display panel or a Mini-LED or a Micro-LED. When the structure in FIG. 6H is adapted for the organic light emitting diode display panel, the first electrode PE can be an anode.

The present application also provides a mobile terminal comprising a terminal main part and the above display panel. The terminal main part and the display panel are assembled integrally. The terminal main part can be a device bonded to a circuit board of the display panel and is disposed on a coverplate of the display panel. The mobile terminal can comprise electron apparatuses such as cell phone, television, notebook, etc.

In the above-mentioned embodiments, the descriptions of the various embodiments are focused. For the details of the embodiments not described, reference may be made to the related descriptions of the other embodiments.

The technical solutions provided by the embodiment of the present application are described in detail as above. The principles and implementations of the present application are described in the following by using specific examples. The description of the above embodiments is only for assisting understanding of the technical solutions of the present application and the core ideas thereof. Those of ordinary skill in the art should understand that they can still modify the technical solutions described in the foregoing embodiments or equivalently replace some of the technical features. These modifications or replacements do not make the essence of the technical solutions depart from a range of the technical solutions of the embodiments of the present application.

1. An array substrate, comprising:
an underlay substrate;
an active layer disposed on a side of the underlay substrate, wherein the active layer comprises a channel part and a first conductor part and a second conductor part disposed on two sides of the channel part respectively;
a gate insulation layer comprising a first insulation part and a second insulation part spaced from each other, wherein the first insulation part is disposed on a side of the active layer away from the underlay substrate, and the second insulation part is disposed on an end of the active layer;
a conductive layer disposed on a side of the gate insulation layer away from the underlay substrate, wherein the conductive layer comprises a gate electrode and a drain electrode separated from each other, the gate electrode is located on the first insulation part, an orthographic projection of the gate electrode on the active layer is located in the channel part; the drain electrode is located on the second insulation part, and the drain electrode overlaps a part of the first conductor part; and
a first electrode disposed on a side of the conductive layer away from the underlay substrate, wherein the first electrode is connected to the second conductor part;
wherein along a direction from the first conductor part to the second conductor part, the first conductor part comprises a first length, the second conductor part comprises a second length, and the first length is greater than the second length.

2. The array substrate according to claim 1, wherein a ratio of the first length to the second length ranges from 1.2 to 2.

3. The array substrate according to claim 1, wherein a first via hole is defined between the first insulation part and the second insulation part, the drain electrode contacts a sidewall of the second insulation part and extends along the sidewall to a surface of a side of the first conductor part away from the underlay substrate.

4. The array substrate according to claim 3, wherein the drain electrode comprises an overlap surface contacting the first conductor part, a length of the overlap surface along a direction from the first conductor part to the channel part ranges from 2 microns to 8 microns.

5. The array substrate according to claim 1, wherein the array substrate further comprises:
a first passivation layer disposed on a side of the conductive layer away from the underlay substrate;
a planarization layer disposed on a side of the first passivation layer away from the underlay substrate;
a common electrode disposed on a side of the planarization layer away from the underlay substrate; and
a second passivation layer disposed on a side of the common electrode away from the underlay substrate;
wherein a second via hole is defined in the array substrate and penetrates the second passivation layer, the planarization layer, and the first passivation layer, the first electrode is disposed on a side of the second passivation layer away from the underlay substrate, and the first electrode is connected to the second conductor part through the second via hole.

6. The array substrate according to claim 5, wherein a tilt angle of the second via hole is less than 70°.

7. The array substrate according to claim 1, wherein the array substrate further comprises:
a buffer layer disposed between the underlay substrate and the active layer; and
at least one transmission line configured to transmit a voltage signal, wherein the transmission line and the active layer are disposed on a surface of a side of the buffer layer away from the underlay substrate.

8. The array substrate according to claim 7, wherein a material of the transmission line is the same as a material of the first conductor part and/or a material of the second conductor part.

9. The array substrate according to claim 1, wherein a ratio of the first length to the second length ranges from 1.2 to 2; and a first via hole is defined between the first insulation part and the second insulation part, the drain electrode contacts a sidewall of the second insulation part and extends along the sidewall to a surface of a side of the first conductor part away from the underlay substrate.

10. The array substrate according to claim 1, wherein a ratio of the first length to the second length ranges from 1.2 to 2.

11. An array substrate manufacturing method, comprising:
providing an underlay substrate;
forming an active layer on the underlay substrate;
forming a gate insulation layer on the active layer and defining a first via hole in the gate insulation layer;
implementing a first conductivizing process to the active layer uncovered by the gate insulation layer;
forming a conductive material layer on the gate insulation layer and patterning the conductive material layer such that the conductive material layer forms a conductive layer comprising a gate electrode and a drain electrode, wherein the gate electrode and the drain electrode are separately disposed from each other;
by a self-alignment process, etching the gate insulation layer uncovered by the gate electrode and the drain electrode such that the gate insulation layer forms a first insulation part and a second insulation part spaced from each other, wherein the first insulation part is disposed on a side of the active layer away from the underlay substrate, the second insulation part is disposed at an end of the active layer, the gate electrode is located on the first insulation part, the drain electrode is located on the second insulation part, and the drain electrode overlaps the active layer corresponding to the first via hole;
implementing a second conductivizing process to the active layer uncovered by the gate electrode and the drain electrode such that the active layer corresponding to the gate electrode forms a channel part, the active layer connected to the channel part and near the drain electrode forms a first conductor part, and the active layer connected to the channel part and located away from the drain electrode forms a second conductor part; and
forming a first electrode, connected to the second conductor part, on a side of the conductive layer away from the underlay substrate;
wherein along a direction from the first conductor part to the second conductor part, the first conductor part comprises a first length, the second conductor part comprises a second length, and the first length is greater than the second length.

12. A display panel, comprising an array substrate, wherein the array substrate comprises:
an underlay substrate;
an active layer disposed on a side of the underlay substrate, wherein the active layer comprises a channel part and a first conductor part and a second conductor part disposed on two sides of the channel part respectively;
a gate insulation layer comprising a first insulation part and a second insulation part spaced from each other, wherein the first insulation part is disposed on a side of the active layer away from the underlay substrate, and the second insulation part is disposed on an end of the active layer;
a conductive layer disposed on a side of the gate insulation layer away from the underlay substrate, wherein the conductive layer comprises a gate electrode and a drain electrode separated from each other, the gate electrode is located on the first insulation part, an orthographic projection of the gate electrode on the active layer is located in the channel part; the drain electrode is located on the second insulation part, and the drain electrode overlaps a part of the first conductor part; and
a first electrode disposed on a side of the conductive layer away from the underlay substrate, wherein the first electrode is connected to the second conductor part;
wherein along a direction from the first conductor part to the second conductor part, the first conductor part comprises a first length, the second conductor part comprises a second length, and the first length is greater than the second length.

13. The display panel according to claim 12, wherein a ratio of the first length to the second length ranges from 1.2 to 2.

14. The display panel according to claim 12, wherein a first via hole is defined between the first insulation part and the second insulation part, the drain electrode contacts a sidewall of the second insulation part and extends along the sidewall to a surface of a side of the first conductor part away from the underlay substrate.

15. The display panel according to claim 14, wherein the drain electrode comprises an overlap surface contacting the first conductor part, a length of the overlap surface along a direction from the first conductor part to the channel part ranges from 2 microns to 8 microns.

16. The display panel according to claim 12, wherein the array substrate further comprises:
a first passivation layer disposed on a side of the conductive layer away from the underlay substrate;
a planarization layer disposed on a side of the first passivation layer away from the underlay substrate;
a common electrode disposed on a side of the planarization layer away from the underlay substrate; and
a second passivation layer disposed on a side of the common electrode away from the underlay substrate;
wherein a second via hole is defined in the array substrate and penetrates the second passivation layer, the planarization layer, and the first passivation layer, the first electrode is disposed on a side of the second passivation layer away from the underlay substrate, and the first electrode is connected to the second conductor part through the second via hole.

17. The display panel according to claim 16, wherein a tilt angle of the second via hole is less than 70°.

18. The display panel according to claim 12, wherein the array substrate further comprises:
a buffer layer disposed between the underlay substrate and the active layer; and
at least one transmission line configured to transmit a voltage signal, wherein the transmission line and the active layer are disposed on a surface of a side of the buffer layer away from the underlay substrate.

19. The display panel according to claim 18, wherein a material of the transmission line is the same as a material of the first conductor part and/or a material of the second conductor part.

20. The display panel according to claim 18, wherein a ratio of the first length to the second length ranges from 1.2 to 2; and a first via hole is defined between the first insulation part and the second insulation part, the drain electrode contacts a sidewall of the second insulation part and extends along the sidewall to a surface of a side of the first conductor part away from the underlay substrate.
